(19) United States
(12) Patent Application Publication
(10) Pub. No.: US 2019/0229053 A1
(43) Pub. Date: Jul. 25, 2019

(54) METAL-INSULATOR-METAL CAPACITOR STRUCTURE AND MANUFACTURING METHOD THEREOF

(71) Applicant: UNITED MICROELECTRONICS CORP., Hsin-Chu City (TW)

(72) Inventors: Ya-Jyuan Hung, Kaohsiung City (TW); Ai-Sen Liu, Hsinchu City (TW); Bin-Siang Tsai, Changhua County (TW); Chin-Fu Lin, Tainan City (TW); Chun-Yuan Wu, Yun-Lin County (TW)

(21) Appl. No.: 15/877,340

(22) Filed: Jan. 22, 2018

(51) Int. Cl. H01L 23/522; H01L 49/02; H01L 21/768; H01L 27/01

(52) U.S. Cl. CPC H01L 23/5223; H01L 28/60; H01L 27/016; H01L 21/76852; H01L 21/76834

(57) ABSTRACT

A manufacturing method of a metal-insulator-metal (MIM) capacitor structure includes the following steps. A bottom plate is formed. A first conductive layer is patterned to be the bottom plate, and the first conductive layer includes a metal element. An interface layer is formed on the first conductive layer by performing a nitrous oxide (N₂O) treatment on a top surface of the first conductive layer. The interface layer includes oxygen and the metal element of the first conductive layer. A dielectric layer is formed on the interface layer. A top plate is formed on the dielectric layer. The metal-insulator-metal capacitor structure includes the bottom plate, the interface layer disposed on the bottom plate, the dielectric layer disposed on the interface layer, and the top plate disposed on the dielectric layer.

### BACKGROUND OF THE INVENTION

### 1. Field of the Invention

The present invention relates to a metal-insulator-metal (MIM) capacitor structure and a manufacturing method thereof, and more particularly, to a metal-insulator-metal (MIM) capacitor structure including an interface layer and a manufacturing method thereof.

### 2. Description of the Prior Art

In modern society, the micro-processor systems composed of integrated circuits (ICs) are applied popularly in our living. Many electrical products, such as personal computers, mobile phones, and home appliances, include ICs. With the development of technology and the increasingly imaginative applications of electrical products, the design of ICs tends to be smaller, more delicate and more diversified.

In the recent electrical products, IC devices, such as metal oxide semiconductor (MOS) transistors, capacitors, or resistors, are produced from silicon based substrates that are fabricated by semiconductor manufacturing processes. A complicated IC system may be composed of the IC devices electrically connected with one another. Generally, a capacitor structure may be composed of a top electrode, a dielectric layer, and a bottom electrode. The capacitor structure is traditionally disposed in an inter-metal dielectric (IMD) layer on a silicon based substrate and includes a metal-insulator-metal (MIM) capacitor structure. In the manufacturing process of the MIM capacitor structure, the electrodes are generally formed by a physical vapor deposition process respectively, and the surface of electrode is relatively rough because of the deposition mechanism of the physical vapor deposition process. The surface roughness of the electrode will influence the interface condition between the electrode and the dielectric layer, and the electrical performance and reliability of the MIM capacitor structure will be deteriorated accordingly.

### SUMMARY OF THE INVENTION

A metal-insulator-metal (MIM) capacitor structure and a manufacturing method thereof are provided in the present invention. An interface layer is formed by performing a nitrous oxide (N₂O) treatment on a top surface of a first conductive layer, and the first conductive layer is patterned to be a bottom plate. The interface layer is located between the bottom plate and a dielectric layer for improving the interface condition between the bottom plate and the dielectric layer and reducing the influence of surface roughness of the bottom plate on the electrical performance and reliability of the MIM capacitor structure.

According to an embodiment of the present invention, a manufacturing method of a metal-insulator-metal capacitor structure is provided. The manufacturing method includes the following steps. A bottom plate is formed. A first conductive layer is patterned to be the bottom plate, and the first conductive layer includes a metal element. An interface layer is formed on the first conductive layer by performing a nitrous oxide treatment on a top surface of the first conductive layer. The interface layer includes oxygen and the metal element of the first conductive layer. A dielectric layer is formed on the interface layer. A top plate is formed on the dielectric layer.

According to an embodiment of the present invention, a metal-insulator-metal capacitor structure is provided. The metal-insulator-metal capacitor structure includes a bottom plate, an interface layer, a dielectric layer, and a top plate. The bottom plate includes a metal element. The interface layer is disposed on the bottom plate. The interface layer includes oxygen and the metal element of the bottom plate. The dielectric layer is disposed on the interface layer. The top plate is disposed on the dielectric layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating a metal-insulator-metal (MIM) capacitor structure according to an embodiment of the present invention.

FIGS. 2-6 are schematic drawings illustrating a manufacturing method of a metal-insulator-metal capacitor structure according to an embodiment of the present invention, wherein

FIG. 3 is a schematic drawing in a step subsequent to FIG. 2,

FIG. 4 is a schematic drawing in a step subsequent to FIG. 3,

FIG. 5 is a schematic drawing in a step subsequent to FIG. 4, and

FIG. 6 is a schematic drawing in a step subsequent to FIG. 5.

### DETAILED DESCRIPTION

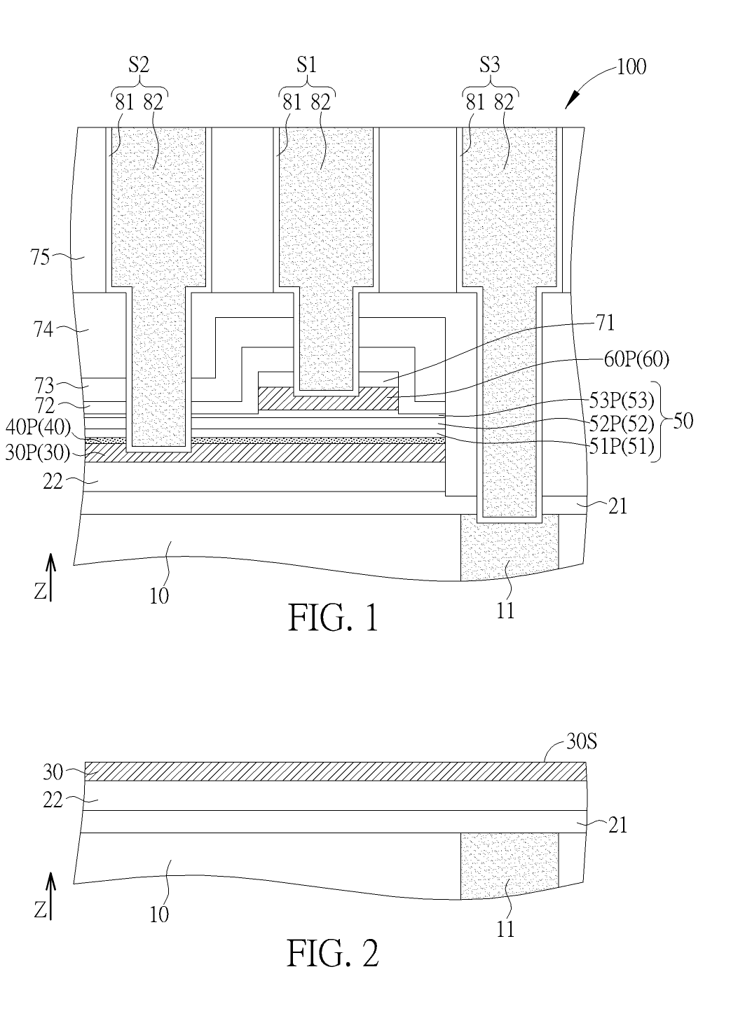

Please refer to FIG. 1. FIG. 1 is a schematic drawing illustrating a metal-insulator-metal (MIM) capacitor structure according to an embodiment of the present invention. As shown in FIG. 1, a metal-insulator-metal capacitor structure 100 in this embodiment includes a bottom plate 30P, an interface layer 40, a dielectric layer 50, and a top plate 60P. The bottom plate 30P includes a metal element. In some embodiments, the bottom plate 30P may include titanium nitride (TiN), tantalum nitride (TaN), or other suitable conductive materials. Therefore, the metal element of the bottom plate 30P may include titanium, tantalum, or other suitable metal elements. The interface layer 40 is disposed on the bottom plate 30P. The interface layer 40 includes oxygen and the metal element of the bottom plate 30P. In some embodiments, the interface layer 40 may include an oxide of the metal element of the bottom plate 30P and/or an oxynitride of the metal element of the bottom plate 30P. For example, the interface layer 40 may include titanium oxide, tantalum oxide, titanium oxynitride, or tantalum oxynitride, but not limited thereto. The dielectric layer 50 is disposed on the interface layer 40, and the dielectric layer 50 is different from the interface layer 40. In some embodiments, the dielectric layer 50 may include a high dielectric constant (high-k) dielectric material for increasing the capacitance of the MIM capacitor structure 100, but not limited thereto. The high-k material mentioned above may include hafnium oxide (HfO₂), hafnium silicon oxide (HfSiO₄), hafnium silicon oxynitride (HfSiON), aluminum oxide (Al₂O₃), zirconium oxide (ZrO₂), or other suitable high-k materials. Additionally, the dielectric layer 50 may be a single layer or a multiple layer structure. For example, the dielectric layer 50 may include a first high-k layer 51, a second high-k layer 52, and a third high-k layer 53 stacked in a thickness direction of the dielectric layer 50 (such as a direction Z shown in FIG. 1). The first high-k layer 51, the second high-k layer 52, and the third high-k layer 53 may include one of the high-k materials mentioned above respectively, and the second high-k layer 52 may be different from the first high-k layer 51 and the third high-k layer 53. For instance, the first high-k layer 51 may be a zirconium oxide layer, the second high-k layer 52 may be an aluminum oxide layer, and the third high-k layer 53 may be another zirconium oxide layer. In other words, the dielectric layer 50 may include a stacked zirconium oxide-aluminum oxide-zirconium oxide (ZAZ) structure, but not limited thereto. The top plate 60P is disposed on the dielectric layer 50. The interface layer 40 is disposed between the dielectric layer 50 and the bottom plate 30P for improving the interface condition between the bottom plate 30P and the dielectric layer 50 and reducing the influence of surface roughness of the bottom plate 30P on the electrical performance and reliability of the MIM capacitor structure 100. Additionally, for reducing the influence of the interface layer 40 on the capacitance of the MIM capacitor structure 100, the interface layer 40 should be as thin as possible and still be capable of improving the interface condition between the bottom plate 30P and the dielectric layer 50. Therefore, the interface layer 40 may be thinner than the dielectric layer 50. In some embodiments, the interface layer 40 may be thinner than the first high-k layer 51, the second high-k layer 52, and the third high-k layer 53 respectively, but not limited thereto.

In some embodiments, the MIM capacitor structure 100 may be disposed on a first dielectric layer 10. The first dielectric layer 10 may be disposed on a substrate (not shown), and an interconnection structure 11 may be disposed in the first dielectric layer 10, but not limited thereto. The substrate mentioned above may include a semiconductor substrate or a non-semiconductor substrate. The semiconductor substrate may include a silicon substrate, a silicon germanium substrate, or a silicon-on-insulator (SOI) substrate, and the non-semiconductor substrate may include a glass substrate, a plastic substrate, or a ceramic substrate, but not limited thereto. In addition, other devices, such as transistors, may be formed on the substrate before the steps of forming the first dielectric layer and the interconnection structure 11 according to other considerations, and the MIM capacitor structure 100 may be electrically connected to other devices via the interconnection structure 11 and/or other connection structures, but not limited thereto. In some embodiments, some dielectric layers may be disposed between the bottom plate 30P and the first dielectric layer 10, such as a second dielectric layer 21 and a third dielectric layer 22, but not limited thereto. In some embodiments, some dielectric layers may be formed covering the MIM capacitor structure 100, such as a fourth dielectric layer 72, a fifth dielectric layer 73, a sixth dielectric layer 74, and a seventh dielectric layer 75, but not limited thereto. The first dielectric layer 10, the second dielectric layer 21, the third dielectric layer 22, the fourth dielectric layer 72, the fifth dielectric layer 73, the sixth dielectric layer 74, and the seventh dielectric layer 75 may respectively include dielectric materials such as silicon oxide, silicon nitride, silicon oxynitride, tetraethyl orthosilicate (TEOS), nitrogen doped carbide (NDC), or other suitable dielectric materials. In some embodiments, a first connection structure S1 may penetrate the dielectric layers above the top plate 60P for contacting and being electrically connected with the top plate 60P, and a second connection structure S2 may penetrate the dielectric layers above the bottom plate 30P for contacting and being electrically connected with the bottom plate 30P, but not limited thereto.

Please refer to FIGS. 1-6. FIGS. 2-6 are schematic drawings illustrating a manufacturing method of a metal-insulator-metal (MIM) capacitor structure according to an embodiment of the present invention, and FIG. 1 may be regarded as a schematic drawing in a step subsequent to FIG. 6. As shown in FIG. 1, the manufacturing method of the MIM capacitor structure in this embodiment may include the following steps. The bottom plate 30P is formed on the first dielectric layer 10. A first conductive layer 30 may be patterned to be the bottom plate 30P, and the first conductive layer 30 includes a metal element. In some embodiments, the first conductive layer 30 may include titanium nitride, tantalum nitride, or other suitable conductive materials. Therefore, the metal element of the first conductive layer 30 may include titanium, tantalum, or other suitable metal elements. The interface layer 40 is formed on the first conductive layer 30, and the interface layer 40 includes oxygen and the metal element of the first conductive layer 30. In some embodiments, the interface layer 40 may include an oxide of the metal element of the first conductive layer 30 and/or an oxynitride of the metal element of the first conductive layer 30. The dielectric layer 50 is formed on the interface layer 40, and the top plate 60P is formed on the dielectric layer 50.

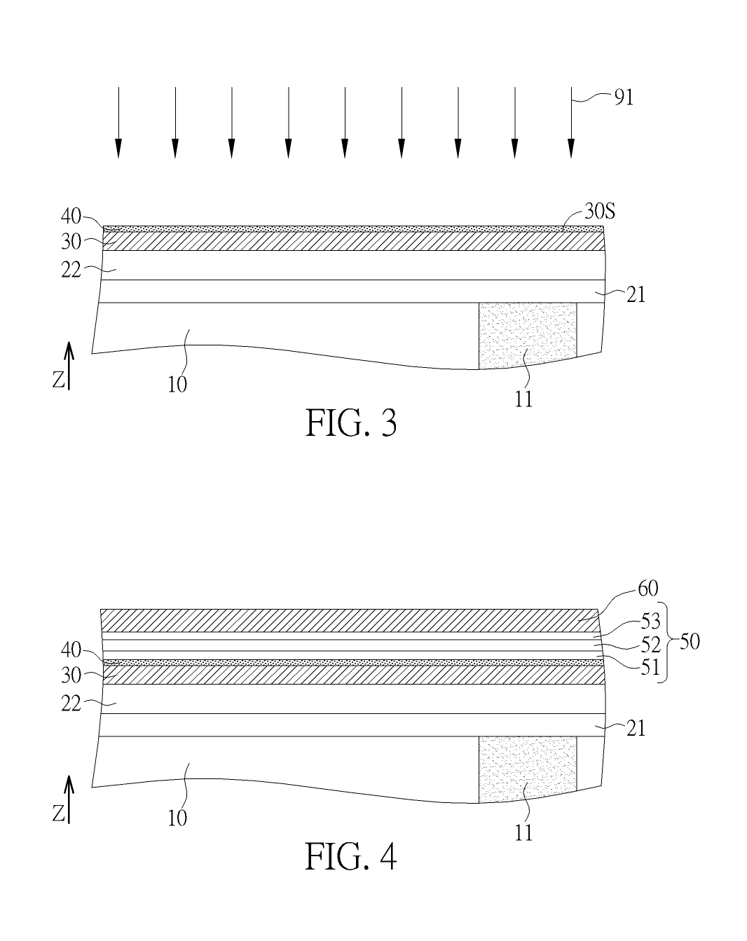

Specifically, as shown in FIG. 2, the second dielectric layer 21 and the third dielectric layer 22 may be formed on the first dielectric layer 10 and the interconnection structure 11 before the step of forming the first conductive layer 30. The material of the second dielectric layer 21 may be different from the material of the third dielectric layer 22 for subsequent etching processes, but not limited thereto. In some embodiments, the first conductive layer 30 may be formed by a physical vapor deposition (PVD) process, and the first conductive layer 30 may have a columnar grain structure. Therefore, the top surface 30S of the first conductive layer 30 may be relatively rough because of the columnar grain structure generated by the PVD process. As shown in FIG. 3, the interface layer 40 is formed on the first conductive layer 30 by performing a nitrous oxide (N₂O) treatment 91 on the top surface 30S of the first conductive layer 30. In some embodiments, the N₂O treatment 91 may be performed in a chemical vapor deposition (CVD) apparatus, but the present invention is not limited to this. In some embodiments, the N₂O treatment 91 may be performed in other kinds of apparatus, such as in a treatment chamber connected with the apparatus of forming the first conductive layer 30. Additionally, for controlling the thickness of the interface layer 40 and preventing oxidizing the grain boundaries of the first conductive layer 30 too seriously, the flow rate of N₂O in the N₂O treatment 91 and radio frequency (RF) power of the N₂O treatment 91 cannot be too high. For example, the flow rate of N₂O in the N₂O treatment 91 may be lower than or equal to 6000 standard cubic centimeters per minute (sccm), and the RF power of the N₂O treatment 91 may be lower than or equal to 2000 watts (W). In some embodiments, the flow rate of N₂O in the N₂O treatment 91 may range from 2000 sccm to 6000 sccm, the RF power of the N₂O treatment 91 may range from 300 W to 2000 W, the temperature of the N₂O treatment 91 may be 400±50 degrees Celsius, and the time of the N₂O treatment 91 may range from 2 seconds to 100 seconds, but not limited thereto. The interface layer 40 formed by the N₂O treatment 91 may protect the grain boundaries of the first conductive layer 30 from being further oxidized in the subsequent process of forming the dielectric layer, and the interface traps may be reduced accordingly. Related electrical performance of the MIM capacitor structure, such as breakdown voltage (Vbd) and time dependent dielectric breakdown (TDDB), may be improved by the interface layer 40 formed by the N₂O treatment 91.

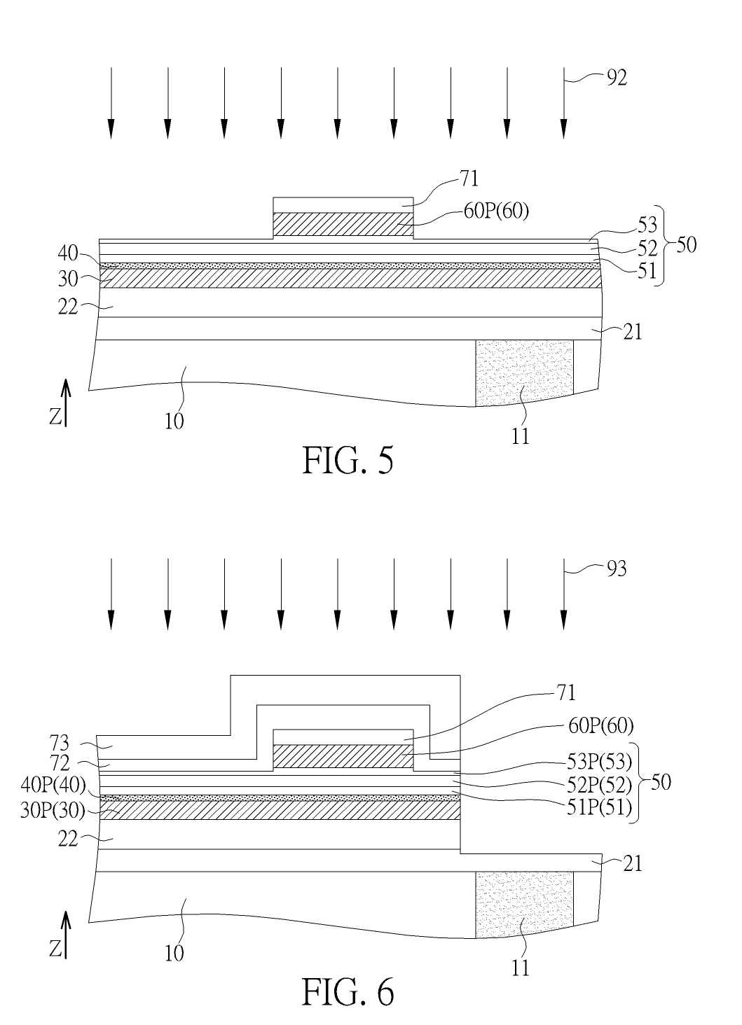

As shown in FIG. 3, FIG. 4 and FIG. 5, the dielectric layer 50 is formed after the N₂O treatment 91, and a second conductive layer 60 is formed on the dielectric layer 50. The second conductive layer 60 is patterned to be the top plate 60P by a first patterning process 92. The second conductive layer 60 may include titanium nitride, tantalum nitride, or other suitable conductive materials. In some embodiments, the first patterning process 92 may include a photolithographic process and an etching process, and a cap layer 71 formed on the second conductive layer 60 may be used to define the top plate 60P in the etching process, but not limited thereto. As shown in FIG. 6, a second patterning process 93 is performed. The first conductive layer 30 may be patterned to be the bottom plate 30P mentioned above by the second patterning process 93. In some embodiments, the step of patterning the second conductive layer 60 may be performed before the step of patterning the first conductive layer 30. Therefore, the dielectric layer 50 may be formed before the step of patterning the first conductive layer 30 and after the N₂O treatment mentioned above, and the N₂O treatment maybe performed before the step of patterning the first conductive layer 30, but not limited thereto. The interface layer 40 and the dielectric layer 50 may also be patterned by the second patterning process 93. For example, the interface layer 40, the first high-k layer 51, the second high-k layer 52, and the third high-k layer 53 may be patterned to be a patterned interface layer 40P, a first patterned high-k layer 51P, a second patterned high-k layer 52P, and a third patterned high-k layer 53P respectively. In some embodiments, the second patterning process 93 may include a photolithographic process and an etching process, and the fourth dielectric layer 72 and/or the fifth dielectric layer 73 may be used to define the bottom plate 30P, the patterned interface layer 40P, the first patterned high-k layer 51P, the second patterned high-k layer 52P, and the third patterned high-k layer 53P in the etching process, but not limited thereto. Therefore, a projection area of the bottom plate 30P, a projection area of the patterned interface layer 40P, and a projection area of the dielectric layer 50 after the second patterning process 93 may be substantially equal to one another in the direction Z, but not limited thereto. In addition, the projection area of the top plate 60P in the direction Z is smaller than the projection area of the bottom plate 30P in the direction Z preferably because there has to be space for forming a connection structure on the bottom plate 30P, but not limited thereto.

As shown in FIG. 6 and FIG. 1, the sixth dielectric layer 74 and the seventh dielectric layer 75 may be formed after the second patterning process 93. The first connection structure S1 may penetrate the seventh dielectric layer 75, the sixth dielectric layer 74, the fifth dielectric layer 73, the fourth dielectric layer 72, and the cap layer 71 for contacting the top plate 60P. The second connection structure S2 may penetrate the seventh dielectric layer 75, the sixth dielectric layer 74, the fifth dielectric layer 73, the fourth dielectric layer 72, the dielectric layer 50, and the interface layer for contacting the bottom plate 30P. Additionally, a third connection structure S3 may be formed penetrating the seventh dielectric layer 75, the sixth dielectric layer 74, and the second dielectric layer 21 for contacting the interconnection structure 11. The first connection structure S1, the second connection structure S2, and the third connection structure S3 may be formed in different trenches respectively and may respectively include a barrier layer 81 and a low resistivity material layer 82. The barrier layer 81 may include titanium nitride, tantalum nitride, or other suitable barrier materials, and the low resistivity material layer 82 may include materials with relatively lower resistivity, such as copper, aluminum, and tungsten, but not limited thereto. Additionally, in some embodiments, the interconnection structure 11 and the third connection structure S3 may be interconnection structures formed on the substrate having semiconductor devices, and the first connection structure S1, the second connection structure S2, and the third connection structure S3 may be formed together by the same manufacturing process. In other words, the manufacturing method of the MIM capacitor structure may be integrated with the manufacturing method of the interconnection structures, but not limited thereto.

To summarize the above descriptions, in the MIM capacitor structure and the manufacturing method thereof according to the present invention, the interface layer is formed by the N₂O treatment on the top surface of the first conductive layer which is going to be patterned to be the bottom plate. The breakdown voltage and the time dependent dielectric breakdown (TDDB) may be improved by the interface layer formed by the N₂O treatment. Accordingly, the electrical performance and the reliability of the MIM capacitor structure may be enhanced by the interface layer of the present invention.

Those skilled in the art will readily observe that numerous modifications and alterations of the device and method may be made while retaining the teachings of the invention. Accordingly, the above disclosure should be construed as limited only by the metes and bounds of the appended claims.

1. A manufacturing method of a metal-insulator-metal (MIM) capacitor structure, comprising:
forming a bottom plate, wherein a first conductive layer is patterned to be the bottom plate, and the first conductive layer comprises a metal element;
forming an interface layer on the first conductive layer by performing a nitrous oxide (N₂O) treatment on a top surface of the first conductive layer, wherein the interface layer comprises oxygen and the metal element of the first conductive layer, and the interface layer comprises an oxynitride of the metal element of the first conductive layer;
forming a dielectric layer on the interface layer; and
forming a top plate on the dielectric layer.

2. (canceled)

3. The manufacturing method of the MIM capacitor structure according to claim 1, wherein the first conductive layer comprises titanium nitride (TiN) or tantalum nitride (TaN).

4. The manufacturing method of the MIM capacitor structure according to claim 1, wherein a flow rate of N₂O in the N₂O treatment is lower than or equal to 6000 standard cubic centimeters per minute (sccm).

5. The manufacturing method of the MIM capacitor structure according to claim 1, wherein the N₂O treatment is performed in a chemical vapor deposition apparatus, and radio frequency (RF) power of the N₂O treatment is lower than or equal to 2000 watts.

6. The manufacturing method of the MIM capacitor structure according to claim 1, wherein the interface layer is thinner than the dielectric layer.

7. The manufacturing method of the MIM capacitor structure according to claim 1, wherein the dielectric layer is formed before the step of patterning the first conductive layer and after the N₂O treatment.

8. The manufacturing method of the MIM capacitor structure according to claim 1, wherein the N₂O treatment is performed before the step of patterning the first conductive layer.

9. The manufacturing method of the MIM capacitor structure according to claim 1, wherein a second conductive layer is patterned to be the top plate, and the step of patterning the second conductive layer is performed before the step of patterning the first conductive layer.

10. The manufacturing method of the MIM capacitor structure according to claim 1, wherein the dielectric layer comprises a stacked zirconium oxide-aluminum oxide-zirconium oxide (ZAZ) structure.

11. A metal-insulator-metal (MIM) capacitor structure, comprising:
a bottom plate, wherein the bottom plate comprises a metal element;
an interface layer disposed on the bottom plate, wherein the interface layer comprises oxygen and the metal element of the bottom plate, and the interface layer comprises an oxynitride of the metal element of the bottom plate;
a dielectric layer disposed on the interface layer; and
a top plate disposed on the dielectric layer.

12. (canceled)

13. The MIM capacitor structure according to claim 11, wherein the bottom plate comprises titanium nitride (TiN) or tantalum nitride (TaN).

14. The MIM capacitor structure according to claim 11, wherein the interface layer is thinner than the dielectric layer.

15. The MIM capacitor structure according to claim 11, wherein the dielectric layer comprises a stacked zirconium oxide-aluminum oxide-zirconium oxide (ZAZ) structure.
